(19) United States
(12) Patent Application Publication
(10) Pub. No.: US 2025/0080082 A1
(43) Pub. Date: Mar. 6, 2025

(54) BULK ACOUSTIC WAVE RESONATOR AND PREPARATION METHOD THEREOF

(71) Applicant: SHANGHAI INSTITUTE OF MICROSYSTEM AND INFORMATION TECHNOLOGY, CHINESE ACADEMY OF SCIENCES, Shanghai (CN)

(72) Inventors: Zhiqiang MU, Shanghai (CN); Congquan ZHOU, Shanghai (CN); Wenjie YU, Shanghai (CN)

(73) Assignee: SHANGHAI INSTITUTE OF MICROSYSTEM AND INFORMATION TECHNOLOGY, CHINESE ACADEMY OF SCIENCES, Shanghai (CN)

(21) Appl. No.: 18/953,129

(22) Filed: Nov. 20, 2024

(30) Foreign Application Priority Data
Mar. 10, 2023 (CN) 2023102295957
Mar. 10, 2023 (CN) 2023102296076
Mar. 10, 2023 (CN) 2023102296362

(51) Int. Cl. H03H 9/17; H03H 3/02; H03H 9/13

(52) U.S. Cl. CPC H03H 9/178; H03H 3/02; H03H 9/13; H03H 9/173; H03H 9/175; H03H 2003/021; H03H 2003/025

(57) ABSTRACT

A bulk acoustic wave resonator and a preparation method thereof, the bulk acoustic wave resonator includes a first electrode and a second electrode, and a piezoelectric film between the first and second electrodes, the piezoelectric film includes n layers of polarized piezoelectric films, and the polarities of any two adjacent layers of the polarized piezoelectric films are opposite. The acoustic mirror is disposed between the substrate and the first electrode, by preparing the polarized piezoelectric films with opposite polarities in layers, polarity inversion is achieved. The bulk acoustic wave resonator of the present disclosure can reduce the requirements for the piezoelectric film materials and increase the resonant frequency under the condition of not reducing the total thickness of the piezoelectric film or introducing a transition electrode. The process is simplified, the acoustic wave loss is reduced, and the quality factor is improved.

### CROSS REFERENCE TO RELATED APPLICATION

This is a continuation application claiming the benefit of priority to a pending PCT application PCT/CN2023/094376, filed on May 15, 2023, entitled “BULK ACOUSTIC WAVE RESONATOR AND PREPARATION METHOD THEREOF”, which claims to the priority of Chinese Patent Application No. CN 2023102296076, filed on Mar. 10, 2023, entitled “STRUCTURE OF BULK ACOUSTIC WAVE RESONATOR”, and Chinese Patent Application No. CN 2023102296362, filed on Mar. 10, 2023, entitled “BULK ACOUSTIC WAVE RESONATOR AND PREPARATION METHOD THEREOF”, and Chinese Patent Application No. CN 2023102295957, filed on Mar. 10, 2023, entitled “TUNING METHOD OF BULK ACOUSTIC WAVE RESONATOR”, the disclosure of all are incorporated herein by reference in their entireties, including any appendices or attachments thereof, for all purpose.

### FIELD OF TECHNOLOGY

The present disclosure relates to the field of microelectronic devices, and in particular to a bulk acoustic wave resonator and a preparation method thereof.

### BACKGROUND

With the development of wireless communication technology, electronic technology is marching towards 5G and developing in the direction of being smaller, lighter and thinner. Piezoelectric radio-frequency (RF) micro-electro-mechanical system (MEMS) resonators have been used as the front-end of RF systems to achieve frequency-selection and interference-suppression functions. Their working principle is to utilize piezoelectric films to realize the conversion between mechanical energy and electrical energy.

The modern communication industry has increasingly high requirements for signal quality, and the competition for communication spectrum resources is becoming more and more intense. Low loss, wide bandwidth, tunability and temperature stability have become the common goals in the communication industry. Acoustic resonators include surface acoustic wave (SAW) resonators and bulk acoustic wave (BAW) resonators. BAW devices have an extremely high Q-value (above 4000) and an operating frequency band range from 100 MHz to 20 GHz. Due to advantages such as high operating frequency, low insertion loss, high-frequency selectivity, high power-handling capacity and strong anti-static ability; currently, they have been widely used in the communication field. Moreover, since the resonance frequency is inversely proportional to the thickness of the piezoelectric film, a relatively high frequency can be easily achieved by thinning the piezoelectric film.

Since the resonant frequency of the traditional single-layer bulk acoustic wave resonator is positively correlated with the ratio of the longitudinal acoustic velocity to the film thickness, this means that the thickness of the piezoelectric film of the filter applied in the higher-frequency bands of 5G will be smaller, and higher requirements for the crystal quality of the film and the process precision are demanded. Some existing solutions include using ferroelectric material stacking and tuning by adjusting the polarity of materials with an applied bias voltage. However, this method requires the growth of a transition electrode for applying the bias voltage between different layers of ferroelectric materials. The decline in crystal quality or the introduction of the transition electrode will lead to a decrease in the power-handling capacity, electromechanical coupling coefficient and Q-value of the thin-film resonator. Therefore, it is urgent to find other control methods to increase the frequency of the resonator.

It should be noted that the above introduction to the technical background is only for clearly and completely explaining the technical solutions of the present disclosure and facilitating the understanding of those skilled in the art. Although these solutions are expounded in the background technology section of this application, it cannot be considered that the above-mentioned technical solutions are well-known to those skilled in the art.

### SUMMARY

The present disclosure provides a bulk acoustic wave resonator and a preparation method thereof.

The bulk acoustic wave resonator includes:
a substrate;
a first electrode, disposed above the substrate, wherein an acoustic mirror is disposed between the substrate and the first electrode, and the acoustic mirror is used for reflecting acoustic waves to produce resonance;
a piezoelectric film, disposed on the first electrode, wherein the piezoelectric film comprises n layers of polarized piezoelectric films, and polarities of any two adjacent layers of the polarized piezoelectric films are opposite, wherein n≥2; and
a second electrode, disposed on the piezoelectric film.

Optionally, a thickness of each of the polarized piezoelectric films is not less than 50 nm; a total thickness of the piezoelectric film ranges from 100 nm to 4000 nm.

Optionally, by maintaining a total thickness of the piezoelectric film constant and changing a quantity of layers of the polarized piezoelectric films of different polarities, tuning of the bulk acoustic wave resonator is achieved.

Optionally, polarized piezoelectric films of different polarities have a same thickness or different thicknesses; when the thicknesses of the polarized piezoelectric films with different polarities are different, a thickness ratio of the different layers is varied by maintaining a quantity of layers of the polarized piezoelectric films constant.

Optionally, a material of the polarized piezoelectric films is one or more of AlN, AlxGa₍₁₋ₓ₎N, ScxAl₍₁₋ₓ₎N, LiNbO₃, PZT, PbTiO₃, and ZnO, wherein x, y are numbers greater than or equal to 0 and less than or equal to 1.

Optionally, the materials of the polarized piezoelectric films of different polarities are the same, or different.

Optionally, a material of the substrate is one or more of Si, SiN, Ge, SiO₂, SiC and sapphire.

Optionally, the acoustic mirror is an air cavity or a Bragg reflection stack disposed on a surface of the substrate.

Optionally, the air cavity is a cavity formed by a groove in a surface of the substrate and the first electrode; or a support layer is provided on a surface of the substrate, the support layer is patterned to form a hollow portion, the air cavity is a cavity formed by the substrate, and the patterned hollow portion of the support layer and the first electrode.

Optionally, the bulk acoustic wave resonator further comprises an electrode lead-out structure for leading out the first electrode and the second electrode respectively, the electrode lead-out structure including:
a via, penetrating the piezoelectric film to expose a surface of the first electrode;
a first electrode lead-out structure, disposed in the via and connected to the first electrode;
a second electrode lead-out structure, connected to the second electrode.

Optionally, a material of the first electrode is one or more of Au, Ag, Ru, W, Mo, Ir, Al, Pt, Nb and Hf, and a thickness of the material of the first electrode ranges from 100 nm to 300 nm; a material of the second electrode is one or more of Au, Ag, Ru, W, Mo, Ir, Al, Pt, Nb and Hf; a thickness of the material of the second electrode ranges from 100 nm to 300 nm.

The present disclosure also provides a method for preparing a bulk acoustic wave resonator, the method includes:
S11: providing a temporary substrate;
S12: forming a piezoelectric film on the temporary substrate, the piezoelectric film sequentially including n layers of polarized piezoelectric films, any two adjacent layers of the polarized piezoelectric films having opposite polarities, wherein n≥2;
S13: forming a first electrode on the piezoelectric film;
S14: providing a substrate, bonding the substrate to the first electrode to secure the substrate while forming an acoustic mirror between the substrate and the first electrode, and removing the temporary substrate;
S15: forming a second electrode on the piezoelectric film.

Optionally, polarized piezoelectric films of different polarities are grown in the same way, or in different ways.

Optionally, the method further includes S16: preparing an electrode lead-out structure of the first electrode and the second electrode, including:
S21: forming a via penetrating the piezoelectric film and exposing a surface of the first electrode, depositing in the via a first electrode lead-out structure connected to the first electrode;
S22: forming a second electrode lead-out structure connected to the second electrode.

As described above, the bulk acoustic wave resonator of the present disclosure and the preparation method thereof have the following beneficial effects:

The bulk acoustic wave resonator includes a first electrode, a second electrode, and the piezoelectric film sandwiched between the first electrode and the second electrode. The piezoelectric film includes n layers of polarized piezoelectric films, and polarities of any two adjacent layers of the polarized piezoelectric films are opposite. The acoustic mirror is disposed between the substrate and the first electrode, by preparing the polarized piezoelectric films with opposite polarities in layers, polarity inversion is achieved. The bulk acoustic wave resonator of the present disclosure can lower the requirements for the piezoelectric film materials and increase the resonant frequency under the condition of not reducing the total thickness of the piezoelectric film or introducing a transition electrode. The process is simplified, the acoustic wave loss is reduced, and the quality factor is improved. In addition, the more layers of the polarized piezoelectric film there are, the higher-order resonant modes can be excited, and the greater the resonant frequency is. The preparation method of the present disclosure reduces the requirements of process and devices while increasing the filter operating frequency, and provides a new preparation method for high-frequency bulk acoustic wave resonators.

### BRIEF DESCRIPTION OF THE DRAWINGS

FIG. 1 shows a schematic structure of a bulk acoustic wave resonator with n being 2 of the present disclosure.

FIG. 2 shows a schematic structure of a bulk acoustic wave resonator of the present disclosure.

FIG. 3 shows a schematic diagram of a bulk acoustic wave resonator structure in prior art and its vibration mode.

FIG. 4 shows a schematic diagram of a bulk acoustic wave resonator structure of the present disclosure and its vibration mode.

FIG. 5 shows a graph of the COMSOL simulation results of a bulk acoustic wave resonator of the present disclosure.

FIG. 6 shows a schematic diagram of the structure of the experimental group I of the present disclosure.

FIG. 7 shows a graph of the COMSOL simulation results for experimental group I of the present disclosure.

FIG. 8 shows a schematic diagram of the structure of the experimental group II of the present disclosure.

FIG. 9 shows a graph of the COMSOL simulation results for experimental group II of the present disclosure.

FIG. 10 shows a schematic diagram of the structure of the experimental group III of the present disclosure.

FIG. 11 shows a graph of the COMSOL simulation results for experimental group III of the present disclosure.

FIG. 12 shows a schematic diagram of the structure of comparison group I of the present disclosure.

FIG. 13 shows a schematic diagram of the structure of the experimental group IV of the present disclosure.

FIG. 14 shows a schematic flowchart of a method of preparing a bulk acoustic wave resonator of the present disclosure.

FIGS. 15 to 23 show schematic structural diagrams of the steps of the method for preparing the bulk acoustic wave resonator of the present disclosure.

FIG. 24 shows a schematic flowchart of a method of preparing an electrode lead-out structure of the present disclosure.

### REFERENCE NUMERALS

11 Temporary Substrate
12 Substrate
20 Single-layer piezoelectric film
21, 23, 24, 26, 27 First Polarized Piezoelectric Film
22, 25, 28 Second Polarized Piezoelectric Film
31 First Electrode
32 Second Electrode
41 Support Layer
42 Hollow Portion
43 Air Cavity
51 First Electrode Lead-out Structure
52 Second Electrode Lead-out Structure
53 Via
61 First Polarity Direction
62 Second Polarity Direction
71 Unidirectional Stress
72 Compressive Stress
73 Tensile Stress
81 Coupling Layer
S11 to S15, S16, S21 to S22 Steps

### DETAILED DESCRIPTION

The embodiments of the present disclosure will be described below through exemplary embodiments. Those skilled in the art can easily understand other advantages and effects of the present disclosure according to the contents disclosed by the specification. The present disclosure may also be implemented or applied through other different specific implementation modes. Various modifications or changes may be made to all details in the specification based on different points of view and applications without departing from the spirit of the present disclosure.

As in the detailed description of the embodiments of the present disclosure, for the sake of illustration, the sectional drawings representing the structure of the device will not be partially enlarged in accordance with the general scale, and the schematic drawings are only examples, which shall not limit the scope of protection of the present disclosure herein.

For the convenience of description, spatial relation words such as “beneath”, “below”, “lower than”, “underneath”, “above”, “on” may be used here to describe the relationship between one structure or feature and other structures or features shown in the drawings. It will be appreciated that these spatial relationship terms are intended to encompass orientations of the device in use or operation other than those depicted in the accompanying drawings. Furthermore, when a layer is to be “between” two layers, it may be the only layer between the two layers, or there may be one or more intervening layers. The term “between . . . ” is used in the present disclosure to include both endpoint values.

In the context of the present disclosure, the described structure with the first feature “on the top” of the second feature may include embodiments in which the first and second features are formed in direct contact, or may include embodiments in which additional features are formed between the first and second features, such that the first and second features may not be in direct contact.

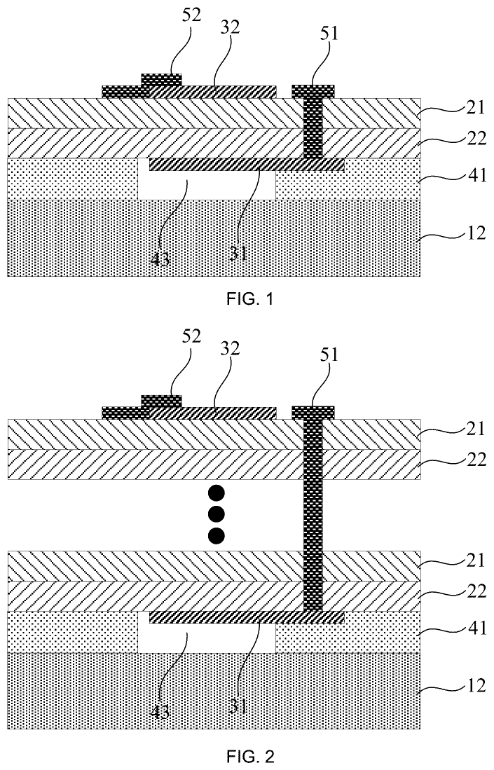

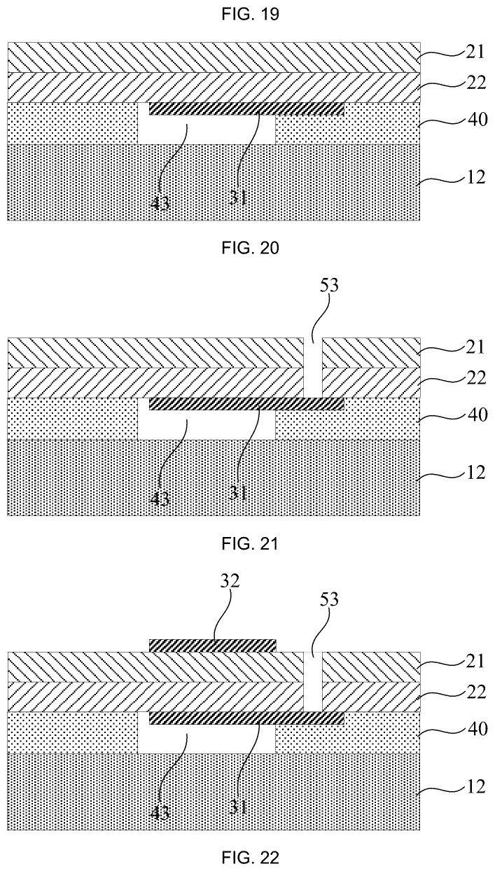

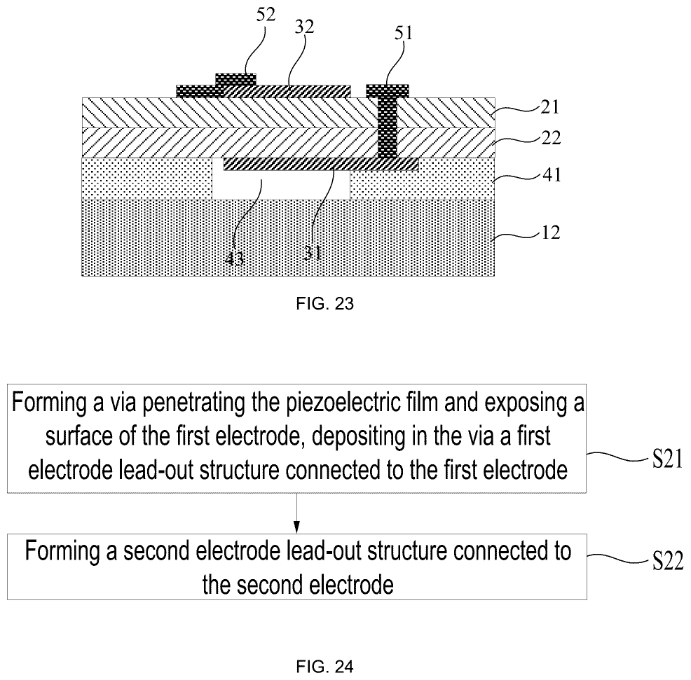

Please refer to FIGS. 1-24. It should be noted that the drawings provided in this disclosure only illustrate the basic concept of the present disclosure in a schematic way, so the drawings only show the components closely related to the present disclosure. The drawings are not necessarily drawn according to the number, shape and size of the components in actual implementation; during the actual implementation, the type, quantity and proportion of each component can be changed as needed, and the layout of the components can also be more complicated.

### Embodiment 1

As shown in FIG. 1, this embodiment provides a bulk acoustic wave resonator, including:
a substrate 12;
a first electrode 31, disposed above the substrate 12, wherein an acoustic mirror is disposed between the substrate 12 and the first electrode 31, the acoustic mirror is used for reflecting acoustic waves to produce resonance;
a piezoelectric film, disposed on the first electrode 31, wherein the piezoelectric film comprises n layers of polarized piezoelectric films, and polarities of any two adjacent layers of the polarized piezoelectric films are opposite, wherein n≥2; and
a second electrode 32, disposed on the piezoelectric film.

The bulk acoustic wave resonator of the present embodiment includes a first electrode 31, a second electrode 32, and the piezoelectric film sandwiched between the first electrode 31 and the second electrode 32. The piezoelectric film includes n layers of polarized piezoelectric films, and the polarities of any two adjacent layers of the polarized piezoelectric films are opposite. The acoustic mirror is disposed between the substrate 12 and the first electrode 31, by preparing the polarized piezoelectric films with opposite polarities in layers, polarity inversion is achieved. The bulk acoustic wave resonator of the present disclosure can reduce the requirements for the piezoelectric film materials and increase the resonant frequency under the condition of not reducing the total thickness of the piezoelectric film or introducing a transition electrode. The process is simplified, the acoustic wave loss is reduced, and the quality factor is improved. In addition, the more layers of polarized piezoelectric films there are, the higher-order resonant modes can be excited, and the greater the resonant frequency is.

The piezoelectric film includes n layers of polarized piezoelectric films, and the polarities of any two adjacent layers of the polarized piezoelectric films are opposite, and n≥2, e.g., n may be 2, 3, 4, 5, 6, etc. The more layers of polarized piezoelectric film there are, the higher-order resonant modes can be excited, and the greater the resonant frequency is.

The number n of the polarized piezoelectric films may be any number while satisfying the total thickness of the piezoelectric films, and the materials of each layer of the polarized piezoelectric films may be stacked in a regular circular pattern or in a stack of any material, as long as it is ensured that the polarities of any two adjacent layers are opposite. As shown in FIG. 1, in one example of this embodiment, n is 2, i.e., the piezoelectric film sequentially includes a first polarized piezoelectric film 21 and a second polarized piezoelectric film 22, the first polarized piezoelectric film 21 and the second polarized piezoelectric film 22 have opposite polarities. As shown in FIG. 2, in another example of this embodiment, the piezoelectric film sequentially includes a plurality of polarized piezoelectric films as a circular stack of the first polarized piezoelectric film 21 with the second polarized piezoelectric film 22.

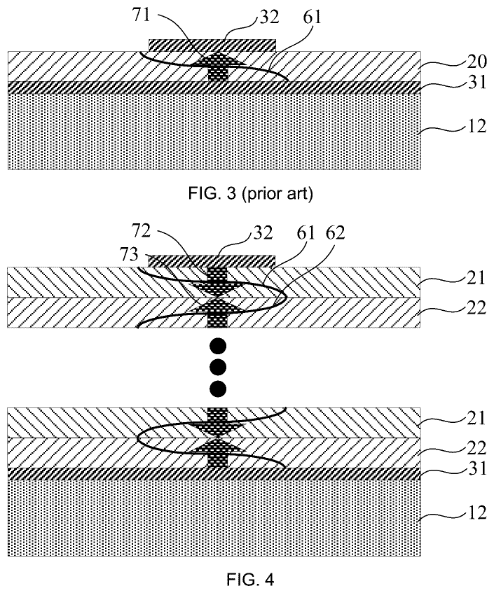

As shown in FIG. 3, the bulk acoustic wave resonator structure in the prior art is made of a single layer piezoelectric film 20, and for ease of viewing, only the basic structure of the bulk acoustic wave resonator in the prior art is shown. Due to the fact that the direction of polarity is single, a first polarity direction 61 is subjected to unidirectional stress 71, and thus produces resonance in a first-order asymmetric resonance mode, with a resonance frequency that is mainly dependent on the thickness of the piezoelectric film. In the methods of the prior art for achieving high-order resonance through polarity inversion to increase the resonance frequency, ferroelectric materials are generally used. Electrodes are grown between piezoelectric films, and the polarity change of the materials is regulated by using the bias voltage method. However, the electrodes between the piezoelectric films will increase the acoustic wave loss of the resonator and reduce the quality factor of the resonator.

As shown in FIG. 4, in this embodiment, by arranging the multi-layered laminated structure of polarized piezoelectric films with opposite polarities, there is a 180° phase difference in the piezoelectric responses to electrical signals generated by any two adjacent layers of polarized piezoelectric films. Using the inverse piezoelectric effect, the adjacent polarized piezoelectric films are respectively subjected to compressive stress 72 and tensile stress 73, causing their polarity directions to be reversed to the second polarity direction 62. This suppresses the first-order asymmetric resonance mode and excites the high-order resonance mode with a higher resonance frequency, thereby increasing the resonance frequency of the bulk acoustic wave resonator without the need to reduce the thickness of the piezoelectric films. At the same time, the piezoelectric film material does not need to be ferroelectric material or electrodes grown between the piezoelectric films, which simplifies the processing, extends the choice of device materials, and facilitates the industrial application of the device, and at the same time, it reduces the acoustic wave loss of the bulk acoustic wave resonator, improves the quality factor, and further enhances the work performance of the resonator.

As an example, the material of the substrate is one or more of Si, SiN, Ge, SiO₂, SiC and sapphire.

The material of the substrate 12 includes and is not limited to the above materials and may be selected according to actual needs. In this embodiment, a Si substrate is preferably used. The shape and size of the substrate 12 can be selected according to actual needs.

As an example, a material of the first electrode is one or more of Au, Ag, Ru, W, Mo, Ir, Al, Pt, Nb and Hf, and a thickness of the material of the first electrode ranges from 100 nm to 300 nm, for example, 100 nm, 150 nm, 200 nm, 250 nm, 300 nm.

In this embodiment, the material of the first electrode 31 is preferably Mo with a thickness of 200 nm. The shape of the first electrode 31 includes, but is not limited to, a regular or irregular shape, such as a circle, an ellipse, a square, a polygon, a an oval, etc., and the specific shape and size of the first electrode 31 may be set according to the actual needs.

As an example, the acoustic mirror is an air cavity 43 or a Bragg reflection stack disposed on a surface of the substrate 12. The air cavity 43 is a cavity formed by a groove in a surface of the substrate 12 and the first electrode 31; or as shown in FIGS. 1 and 2, a support layer 41 is provided on a surface of the substrate 12, the support layer 41 is patterned to form a hollow portion, the air cavity 43 is a cavity formed by the substrate 12, the patterned hollow portion of the support layer 41 and the first electrode 31.

Specifically, where the acoustic mirror is an air cavity 43, the air cavity 43 serves as an acoustic wave reflecting layer. The air cavity 43 arranged between the first electrode 31 and the substrate 12 is to utilize the acoustic impedance of air which is close to 0, so that the acoustic wave at the interface between the first electrode 31 and the air will be completely reflected back into the sandwich structure, which is composed of the second electrode 32, piezoelectric films and first electrode 31, forming a standing wave and thus generating resonance. When the acoustic mirror is a Bragg reflection stack, whose working principle is similar to that of the air cavity 43, the Bragg reflection stack includes a low acoustic impedance layer and a high acoustic impedance layer in multiple alternating layers.

As an example, a material of the polarized piezoelectric films is one or more of AlN, AlxGa₍₁₋ₓ₎N, ScxAl₍₁₋ₓ N, LiNbO₃, PZT, PbTiO₃, and ZnO, wherein x, y are numbers greater than or equal to 0 and less than or equal to 1. The thickness of a single-layer polarized piezoelectric films is not less than 50 nm, for example, 50 nm, 100 nm, 150 nm, 200 nm, 300 nm, 400 nm, 500 nm. The total thickness of the piezoelectric film ranges from 100 nm to 4000 nm, for example, 100 nm, 200 nm, 400 nm, 600 nm, 1000 nm, 2000 nm, 3000 nm, 4000 nm.

In this embodiment, the materials of the first polarized piezoelectric film 21 and the second polarized piezoelectric film 22 are both selected to be AlN of opposite polarities, the single crystal AlN can improve the crystal quality of the piezoelectric film, and thus the resonance performance of the resonator can be further improved. The thicknesses of the single-layer polarized piezoelectric films are both 50 nm, i.e. both the first polarized piezoelectric film 21 and the second polarized piezoelectric film 22 have a thickness of 50 nm, and a total thickness of the piezoelectric films is 100 nm. In this embodiment, the requirement for the thickness of the piezoelectric film is not overly high, and high-frequency resonance can be achieved under the existing precision of the preparation process.

As an example, a material of the second electrode is one or more of Au, Ag, Ru, W, Mo, Ir, Al, Pt, Nb and Hf. The thickness of the material of the second electrode ranges from 100 nm to 300 nm, for example, 100 nm, 150 nm, 200 nm, 250 nm, 300 nm.

In this embodiment, the material selection of the second electrode 32 is the same as that of the first electrode 31, both are Mo with a thickness of 200 nm. A resonator core region is formed by the second electrode 32, the piezoelectric film and the first electrode 31. The shape of the second electrode 32 includes, but is not limited to, a regular or irregular shape of a circle, an ellipse, a square, a polygon, a duck-egg shape, etc., and the specific shape and size of the second electrode 32 may be set according to the actual needs.

A resonator core region is formed by the second electrode 32, the piezoelectric film and the first electrode 31.

As shown in FIGS. 1 to 2, as an example, the bulk acoustic wave resonator further comprises an electrode lead-out structure for leading out the first electrode 31 and the second electrode 32 respectively, the electrode lead-out structure includes:
a via 53, penetrating the piezoelectric film to expose a surface of the first electrode 31;
a first electrode lead-out structure 51, disposed in the via 53 and connected to the first electrode 31; and
a second electrode lead-out structure 52, connected to the second electrode 32.

It is noted herein that in the bulk acoustic wave resonator with the support layer 41, the first electrode 31 generally needs to be patterned, with a portion disposed on the surface of the piezoelectric film in the air cavity 43, and a portion disposed between the piezoelectric film and the support layer 41 to allow the electrode lead-out structure to lead out the first electrode 31.

### Embodiment 2

The present embodiment provides a method of tuning a bulk acoustic wave resonator for tuning a frequency of the bulk acoustic wave resonator of embodiment 1. The tuning method includes maintaining a total thickness of the piezoelectric film constant and changing a quantity of layers of the polarized piezoelectric films of different polarities, to change the amplitudes of resonance peaks of different orders.

The tuning method of the bulk acoustic wave resonator utilizes the layered preparation of the polarized piezoelectric films with opposite polarities, under the conditions of not reducing the total thickness of the piezoelectric films or introducing a transition electrode, it increases the resonant frequency of the resonator, stimulates higher-order resonant modes, simplifies the process, and improves the working frequency of the resonator while reducing the requirements for the process and equipment.

As an example, polarized piezoelectric films of different polarities have the same thickness and the same material.

Using Example 1 as a comparison group, the piezoelectric film of the bulk acoustic wave resonator has a total thickness of 100 nm, the first polarized piezoelectric film 21 and the second polarized piezoelectric film 22 both have a single-layer thickness of 50 nm, and both are made of AlN, although with opposite polarities, and the first electrode 31 and the second electrode 32 both have a thickness of 200 nm, and both are made of Mo.

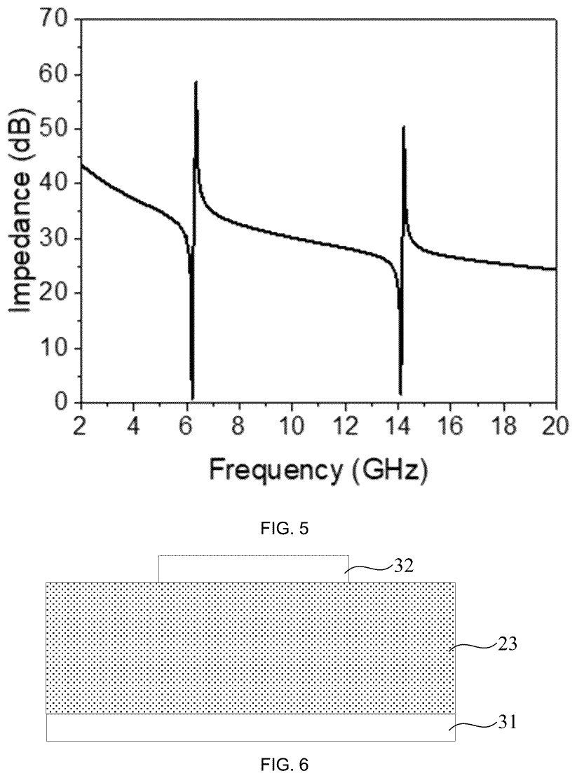

FIG. 5 shows the COMSOL simulation results of Embodiment 1, i.e., FIG. 1. From the simulation results, it can be seen that the strongest resonance peak of the comparison group is near 6 GHZ, i.e., the working frequency band of the bulk acoustic wave resonator of the comparison group can be around 6 GHz.

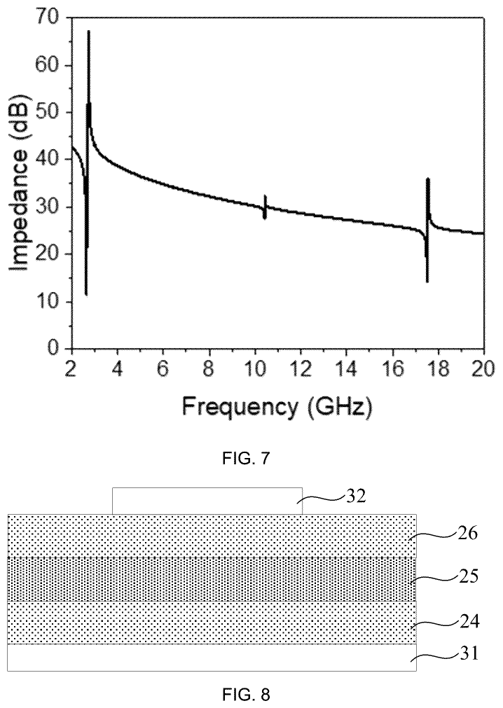

FIGS. 6 and 7 show the structure of the bulk acoustic wave resonator of the experimental group I and its COMSOL simulation results, the total thickness of the piezoelectric film and the first electrode 31 and the second electrode 32 are the same as that of the comparison group, the difference is that the piezoelectric film only includes the first polarized piezoelectric film 23 with the material AlN. For the convenience of viewing, other structures not for comparison are omitted, and it is transformed into a simplified structure of the bulk acoustic wave resonator. As shown in FIG. 7, the strongest resonance peak of the experimental group I is near 3 GHz, which means that the working frequency band of the bulk acoustic wave resonator of the experimental group I can be near 3 GHz.

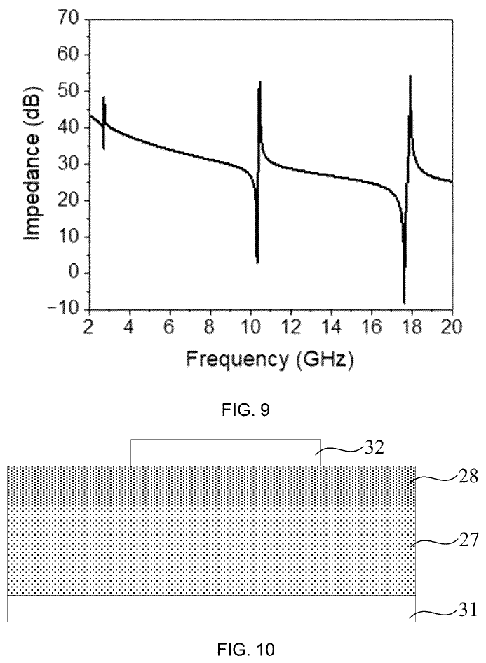

FIGS. 8 and 9 show the structure of the bulk acoustic wave resonator and its COMSOL simulation results for the experimental group II. The total thickness of the piezoelectric film and the first electrode 31 and the second electrode 32 is the same as that of the comparison group, the difference is that the piezoelectric film includes three layers of polarized piezoelectric films with the same thickness, the thickness of a single layer is approximately 33 nm, and the material of all of them is AlN. The three layers of polarized piezoelectric films are respectively the first polarized piezoelectric film 24, the second polarized piezoelectric film 25 and the first polarized piezoelectric film 26 stacked, and the first polarized piezoelectric film 24 is of opposite polarities to the second polarized piezoelectric film 25, and the second polarized piezoelectric film 25 is of opposite polarities to the first polarized piezoelectric film 26. As shown in FIG. 9, the strongest resonance peak of the experimental group II is near 18 GHZ, which means that the working frequency band of the bulk acoustic wave resonator of the experimental group II can be near 18 GHz.

From the strongest resonance peaks of the COMSOL simulation results of the comparison group, experimental group I and experimental group II, it can be seen that the working frequency band of the bulk acoustic wave resonator of the experimental group I can be around 3 GHZ, the working frequency band of the bulk acoustic wave resonator of the comparison group can be around 6 GHZ, and the working frequency band of the bulk acoustic wave resonator of the experimental group II can be around 18 GHz. The more layers of the polarized piezoelectric films of the bulk acoustic wave resonator, the higher-order resonant modes can be excited and the greater the resonant frequency is.

As an example, when thicknesses of polarized piezoelectric films with different polarities are different, a thickness ratio of the different layers is varied by maintaining a quantity of layers of the polarized piezoelectric films constant, and materials of the polarized piezoelectric films with different polarities are different.

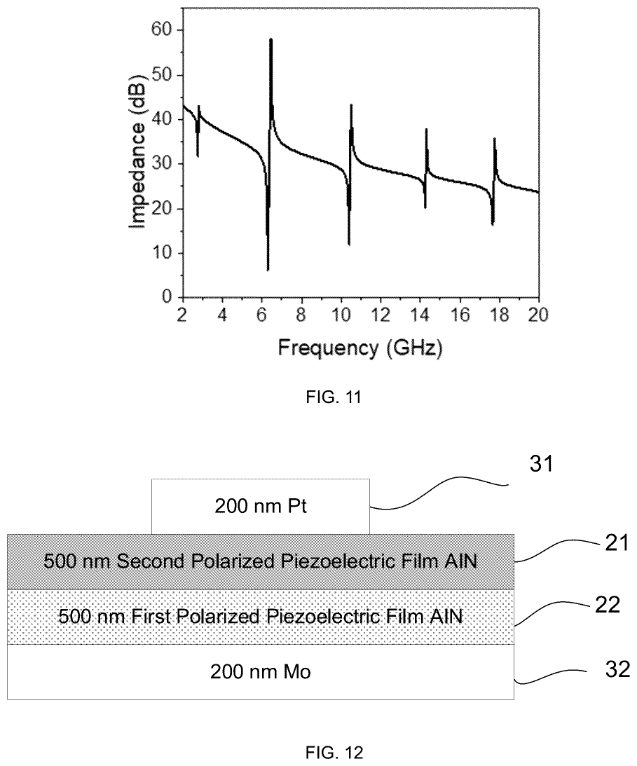

FIGS. 10 and 11 show the structure of the bulk acoustic wave resonator and its COMSOL simulation results for experimental group III. The total thickness of the piezoelectric film and the first electrode 31 and the second electrode 32 is the same as that of the comparison group, the difference is that the piezoelectric film includes two layers of polarized piezoelectric films with different thicknesses, namely, the first polarized piezoelectric film 27 with a thickness of 70 nm and made of AlN, and the second polarized piezoelectric film 28 with a thickness of 30 nm and made of Sc0.7Al0.3N. As shown in FIG. 11, the strongest resonance peak of the experimental group III is near 6 GHZ, which means that the working frequency band of the bulk acoustic wave resonator of the experimental group III can be near 6 GHz.

From the COMSOL simulation results of the comparison group and experimental group III, it can be seen that the working frequency band of the bulk acoustic wave resonator of the comparison group can be around 6 GHZ, and the working frequency band of the bulk acoustic wave resonator of the experimental group Ill can also be around 6 GHz.

When the thicknesses and materials of the polarized piezoelectric films of the bulk acoustic wave resonator are different, it does not affect the result that the more layers of the polarized piezoelectric films of the bulk acoustic wave resonator, the higher-order resonant modes can be excited, and the greater the resonant frequency is.

It should be noted that the thicknesses of the different polarized piezoelectric films are related to the piezoelectric coefficient of the polarized piezoelectric films material. With the quantity of layers of the polarized piezoelectric films fixed, the frequency of the corresponding bulk acoustic wave resonator can be finely tuned by appropriately adjusting the thickness ratio and materials of the polarized piezoelectric films. The specific settings of the thickness ratio and materials can be made according to actual needs.

### Embodiment 3

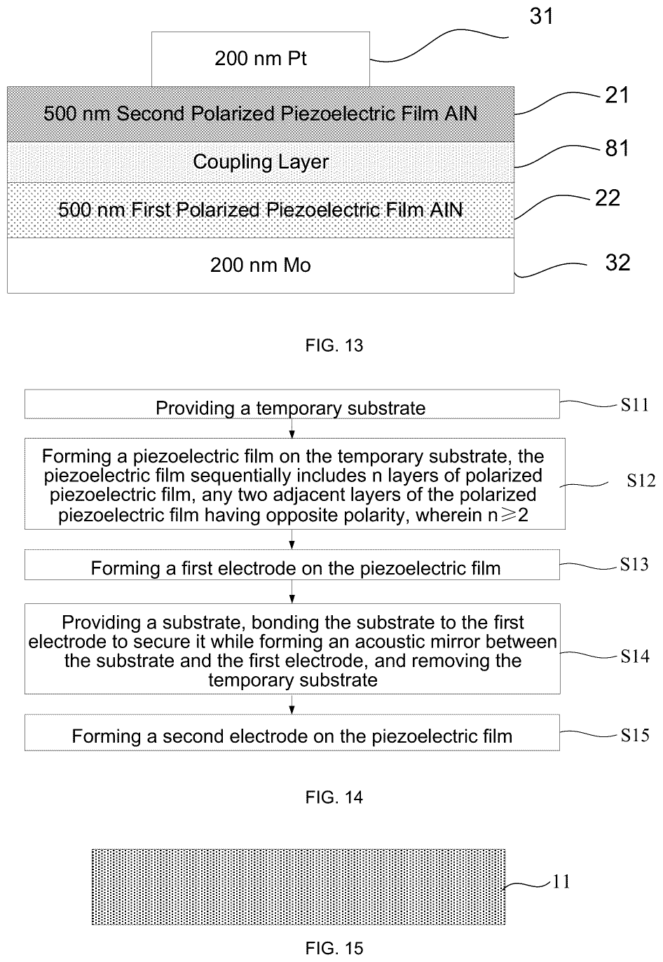

This Embodiment illustrates the effect of introducing a coupling layer in the middle of piezoelectric film materials with different polarities on the performance of the resonator. FIG. 12 shows the schematic structure of the bulk acoustic wave resonator of comparison group I (without a coupling layer), and FIG. 13 shows the schematic structure of the bulk acoustic wave resonator of the experimental group IV.

As shown in FIG. 12, the first polarized piezoelectric film 21 and the second polarized piezoelectric film 22 both have a single-layer thickness of 250 nm and are made of AlN (aluminum nitride) of opposite polarities, and the first electrode 31 and the second electrode 32 both have a thickness of 200 nm and are made of W (tungsten). However, in an actual resonator, the electrode material is not limited to tungsten.

As shown in FIG. 13, the resonator electrode materials and piezoelectric film materials of the experimental group IV are the same as those of comparison group I. The difference lies in that a metal material coupling layer 81 is added between two piezoelectric film materials with different polarities. The material of the coupling layer 81 is one of Al (aluminum), Mo (molybdenum), Os (osmium), and W (tungsten), and the thicknesses of the coupling layer are selected as 30, 50, 70, and 90 nm, respectively.

The COMSOL simulation can be used to determine the effects of different materials and different thicknesses of the coupling layer on the performance of the resonator, and the COMSOL simulation results are shown in Table 1. As can be seen from Table 1, the comparison group I (without a coupling layer) has a higher Q-value and a higher resonant frequency compared to the experimental group IV. The reason is that, due to the introduction of the coupling layer, part of the energy escapes into the coupling layer, resulting in a decrease in the Q-value of the experimental group IV. And according to the mass-loading effect, as the thickness of the coupling layer increases, the resonant frequency decreases, and the greater the density of the coupling layer material is, the more the resonant frequency decreases.

It can be seen that the introduction of transition electrodes (i.e., a coupling layer) leads to a decline in the power handling capability, electromechanical coupling coefficient, and Q value of the piezoelectric film resonator. Therefore, other modulation means are needed to increase the frequency of the resonator.

TABLE 1

| | | The thickness of | | | | | |
|---|---|---|---|---|---|---|---|
| | | the coupling | fs | fp | | | |
| | | layer (nm) | (GHz) | (GHz) | Qs | Qp | BodeQmax |
| without a coupling | | 0 | 9.15 | 9.26 | 1811 | 1118 | 1789 |
| With a | AL | 30 | 8.91 | 9.00 | 1683 | 1009 | 1736 |
| coupling | | 50 | 8.74 | 8.84 | 1671 | 970 | 1672 |
| layer | | 70 | 8.58 | 8.69 | 1613 | 1111 | 1677 |
| | | 90 | 8.41 | 8.52 | 1602 | 1001 | 1662 |
| | Mo | 30 | 8.28 | 8.39 | 1505 | 842 | 1484 |
| | | 50 | 7.78 | 7.90 | 1389 | 982 | 1396 |
| | | 70 | 7.35 | 7.48 | 1334 | 920 | 1362 |
| | | 90 | 6.98 | 7.12 | 1265 | 711 | 1374 |
| | Os | 30 | 7.44 | 7.56 | 1311 | 934 | 1384 |
| | | 50 | 6.68 | 6.81 | 1294 | 543 | 1391 |
| | | 70 | 6.14 | 6.26 | 1150 | 728 | 1345 |
| | | 90 | 5.73 | 5.85 | 1163 | 669 | 1300 |
| | W | 30 | 7.63 | 7.76 | 1338 | 933 | 1384 |
| | | 50 | 6.91 | 7.05 | 1041 | 1025 | 1765 |
| | | 70 | 6.38 | 6.51 | 1182 | 664 | 1377 |
| | | 90 | 5.96 | 6.08 | 1193 | 698 | 1343 |

### Embodiment 4

As shown in FIGS. 14 to 24, the present embodiment provides a method for preparing a bulk acoustic wave resonator, for preparing the bulk acoustic wave resonator of embodiment I. The method includes the following steps:

As shown in FIGS. 14 and 15, step S11 is first performed to provide the temporary substrate 11.

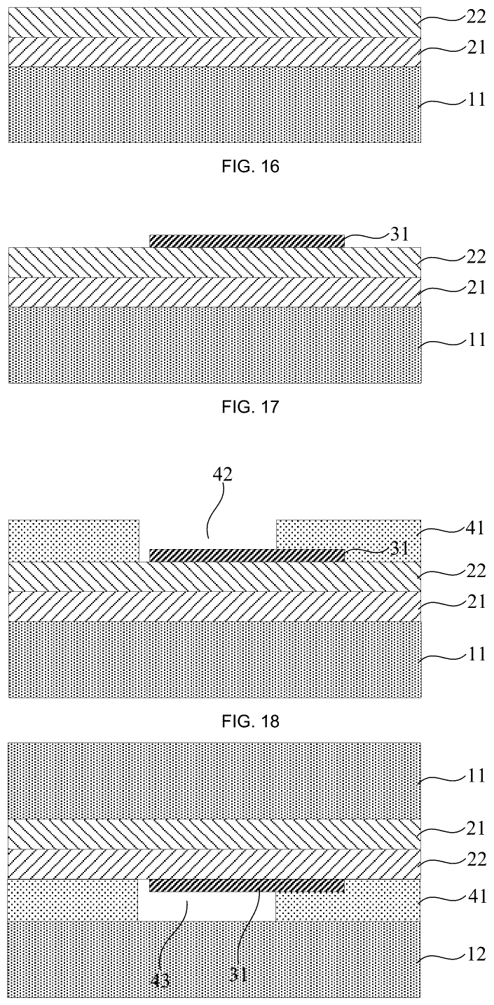

As shown in FIG. 14 and FIG. 16, step S12 is then carried out: a piezoelectric film is formed on the temporary substrate, the piezoelectric film sequentially includes n layers of polarized piezoelectric films, and the polarities of any two adjacent layers of the polarized piezoelectric films are opposite, wherein n≥2.

It should be noted that by maintaining a total thickness of the piezoelectric film constant and changing a quantity of layers of the polarized piezoelectric films of different polarities, tuning of the bulk acoustic wave resonator is achieved.

n may be 2, 3, 4, 5, 6, etc., and in this embodiment, n is 2, i.e., the piezoelectric film sequentially includes a first polarized piezoelectric film 21 and a second polarized piezoelectric film 22, the first polarized piezoelectric film 21 and the second polarized piezoelectric film 22 have opposite polarities.

As examples, the polarized piezoelectric films of different polarities are grown in the same way, or in different ways.

The growth method is any one of Chemical Vapor Deposition (CVD), Metal-organic Chemical Vapor Deposition (MOCVD), Molecular Beam Epitaxy (MBE), Atomic Layer Deposition (ALD), Pulsed Laser Deposition (PLD), Physical Vapor Deposition (PVD), and spin-coating method.

When the preparation methods of the first polarized piezoelectric film 21 and the second polarized piezoelectric film 22 with different polarities are the same, the same growth method can be utilized, and the regulation of different polarities can be achieved by changing the growth process parameters (such as sputtering power) or using doping techniques. When the growth methods of the first polarized piezoelectric film 21 and the second polarized piezoelectric film 22 with different polarities are different, CVD+PVD or PVD+spin-coating method can be adopted.

In an example of this embodiment, the material of the first polarized piezoelectric film 21 and the second polarized piezoelectric film 22 are both AlN, and MOCVD or MBE can be used to grow the first polarized piezoelectric film 21, and PVD may be used to grow the second polarized piezoelectric film 22. It is also possible to dope AlN to grow the first polarized piezoelectric film 21 and the second polarized piezoelectric film 22 with different polarities. The doped AlN includes, but is not limited to, single-element doping and multiple-element doping with elements such as Sc, Mg, Hf, Ti, Zn, Ca, Ba, and the like. All of the above growth methods are set up for the material AlN so that a better crystal quality of AlN can be obtained, to obtain a bulk acoustic wave resonator with better performance.

In another example of this embodiment, the materials of the first polarized piezoelectric film 21 and the second polarized piezoelectric film 22 are materials other than AlN mentioned above. The first polarized piezoelectric film 21 may be grown by PVD, and the second polarized piezoelectric film 22 may be grown by any one of PVD, spin-coating, PVD doping, or adjusting process parameters.

As shown in FIG. 14 and FIG. 17, step S13 is then carried out: a first electrode 31 is formed on the piezoelectric film.

The first electrode 31 is a patterned electrode.

As shown in FIG. 14, step S14 is then carried out: providing a substrate 12, bonding the substrate 12 to the first electrode 31 to secure the substrate while forming an acoustic mirror between the substrate 12 and the first electrode 31, and removing the temporary substrate 11.

As an example, the acoustic mirror is an air cavity 43 or a Bragg reflection stack disposed on a surface of the substrate 12.

The air cavity 43 is a cavity formed by groove in a surface of the substrate 12 and the first electrode 31, and is prepared in two ways, one of which may be to directly provide the substrate 12 provided with a groove and bond it to the first electrode 31 to form the air cavity 43. Another way is shown in FIGS. 16 to 18, where a support layer 41 is formed on the first electrode 31 and the support layer 41 is patterned to form a hollow portion 42 that exposes the first electrode 31, which is then bonded and secured to the substrate 12.

It should be noted that before the bonding, the structure obtained in the previous steps needs to be inverted so that the first electrode 31 or the support layer 41 can be bonded and secured to the substrate 12.

As an example, the material of the support layer 41 is one or more of SiO₂, SiN and Al₂O₃. In this embodiment, SiO₂ is preferably used.

When the support layer 41 is formed on the first electrode 31, it is easy to cause an uneven surface. In this embodiment, the spin-coating method is preferably used, which can directly meet the requirements of the desired flattened surface, and eliminate the need for the step of surface polishing and thinning, simplifying the process and reducing costs.

As an example, the method of forming the hollow portion 42 is any one of dry etching and wet etching.

As shown in FIG. 18, as an example, the hollow portion 42 exposes only the non-electrode lead-out region of the first electrode 31, and the electrode lead-out region of the first electrode 31 is covered by the hollow portion 42.

As shown in FIG. 20, as an example, the method of removing the temporary substrate 11 is any one or a combination of two or more of ion implantation and exfoliation, mechanical grinding, polishing, wet etching, and dry etching, which may be selected according to the actual need.

As shown in FIGS. 21 to 23, a final step S15 is carried out to form a second electrode 32 on the piezoelectric film.

The first electrode 31 is also a patterned electrode.

As shown in FIG. 24, the method for preparing a bulk acoustic wave resonator further includes S16, preparing an electrode lead-out structure of the first electrode 31 and the second electrode 32, including:

step S21 is first carried out to form a via 53 penetrating the piezoelectric film and exposing a surface of the first electrode 31, depositing in the via 53 a first electrode lead-out structure 51 connected to the first electrode 31.

Then, step S22 is performed to form a second electrode lead-out structure 52 connected to the second electrode 32.

As shown in FIGS. 21 to 23, it should be noted that the formation of the second electrode 32 can be either before or after the preparation of the via 53. In this embodiment, preparing the via 53 before forming the second electrode 32 can simplify the process, ending with the preparation of the first electrode lead-out structure 51 and the second electrode lead-out structure 52. In addition, when the second electrode 32 is formed, the electrode material will be simultaneously deposited on the inner wall of the via 53, and finally, the first electrode lead-out structure 51 is formed on the surface of the electrode material, and the second electrode lead-out structure 52 can be formed directly on the surface of the second electrode 32.

As an example, the preparation method of the via 53 is any one of dry etching and wet etching. In this embodiment, ICP dry etching is preferably used to form the via 53.

As an example, the materials of the first electrode lead-out structure 51 and the second electrode lead-out structure 52 are one or more of Ti, Al, Au, Cu and TiN. In this embodiment, a combination of Ti and Au is preferred. The process for preparing the first electrode lead-out structure 51 and the second electrode lead-out structure 52 is any one of a thin film deposition and a patterning process.

In summary, the present disclosure provides a bulk acoustic wave resonator and a preparation method thereof, the bulk acoustic wave resonator including: a substrate; a first electrode, disposed above the substrate, an acoustic mirror is disposed between the substrate and the first electrode, the acoustic mirror is used for reflecting acoustic waves to produce resonance; a piezoelectric film, disposed on the first electrode, the piezoelectric film comprises n layers of polarized piezoelectric films, and polarities of any two adjacent layers of the polarized piezoelectric films are opposite, wherein n≥2; and a second electrode, disposed on the piezoelectric film. The bulk acoustic wave resonator includes a first electrode, a second electrode, and the piezoelectric film sandwiched between the first electrode and the second electrode. The piezoelectric film includes n layers of polarized piezoelectric films, and the polarities of any two adjacent layers of the polarized piezoelectric films are opposite. The acoustic mirror is disposed between the substrate and the first electrode, by preparing the polarized piezoelectric films with opposite polarities in layers, polarity inversion is achieved. The bulk acoustic wave resonator of the present disclosure can reduce the requirements for the piezoelectric film materials and increase the resonant frequency under the condition of not reducing the total thickness of the piezoelectric film or introducing a transition electrode. The process is simplified, the acoustic wave loss is reduced, and the quality factor is improved. In addition, the more layers of the polarized piezoelectric film there are, the higher-order resonant modes can be excited, and the greater the resonant frequency is. The preparation method of the present disclosure reduces the requirements of process and devices while increasing the filter operating frequency, and provides a new preparation method for high-frequency bulk acoustic wave resonators. Therefore, the present disclosure effectively overcomes various shortcomings in the traditional technology and has high industrial utilization value.

The above-mentioned embodiments are merely illustrative of the principle and effects of the present disclosure instead of limiting the present disclosure. Modifications or variations of the above-described embodiments may be made by those skilled in the art without departing from the spirit and scope of the disclosure. Therefore, all equivalent modifications or changes made by those skilled in the art without departing from the spirit and technical concept disclosed by the present disclosure shall be still covered by the claims of the present disclosure.

What is claimed is:

1. A bulk acoustic wave resonator, comprising:
a substrate;
a first electrode, disposed above the substrate, wherein an acoustic mirror is disposed between the substrate and the first electrode, and the acoustic mirror is used for reflecting acoustic waves to produce resonance;
a piezoelectric film, disposed on the first electrode, wherein the piezoelectric film comprises n layers of polarized piezoelectric films, and polarities of any two adjacent layers of the polarized piezoelectric films are opposite, wherein n≥2; and
a second electrode, disposed on the piezoelectric film.

2. The bulk acoustic wave resonator according to claim 1, wherein a thickness of each layer of the polarized piezoelectric films is not less than 50 nm; a total thickness of the piezoelectric films ranges from 100 nm to 4000 nm.

3. The bulk acoustic wave resonator according to claim 1, wherein by maintaining a total thickness of the piezoelectric film constant and changing a quantity of layers of the polarized piezoelectric films of different polarities, tuning of the bulk acoustic wave resonator is achieved.

4. The bulk acoustic wave resonator according to claim 1, wherein polarized piezoelectric films of different polarities have a same thickness or different thicknesses; when the thicknesses of the polarized piezoelectric films with different polarities are different, a thickness ratio of the different layers is varied by maintaining a quantity of layers of the polarized piezoelectric films constant.

5. The bulk acoustic wave resonator according to claim 1, wherein a material of the polarized piezoelectric films is one or more of AlN, AlxGa(1−x)N, ScxAl(1−x)N, LiNbO3, PZT, PbTiO3, and ZnO, wherein x, y are numbers greater than or equal to 0 and less than or equal to 1.

6. The bulk acoustic wave resonator according to claim 5, wherein materials of polarized piezoelectric films of different polarities are the same or different.

7. The bulk acoustic wave resonator according to claim 1, wherein a material of the substrate is one or more of Si, SiN, Ge, SiO₂, SiC and sapphire.

8. The bulk acoustic wave resonator according to claim 1, wherein the acoustic mirror is an air cavity or a Bragg reflection stack disposed on a surface of the substrate.

9. The bulk acoustic wave resonator according to claim 8, wherein the air cavity is a cavity formed by a groove in a surface of the substrate and the first electrode; or a support layer is provided on a surface of the substrate, the support layer is patterned to form a hollow portion, the air cavity is a cavity formed by the substrate, and the patterned hollow portion of the support layer and the first electrode.

10. The bulk acoustic wave resonator according to claim 1, wherein the bulk acoustic wave resonator further comprises an electrode lead-out structure for leading out the first electrode and the second electrode respectively, the electrode lead-out structure comprising:
a via, penetrating the piezoelectric film to expose a surface of the first electrode;
a first electrode lead-out structure, disposed in the via and connected to the first electrode; and
a second electrode lead-out structure, connected to the second electrode.

11. The bulk acoustic wave resonator according to claim 1, wherein a material of the first electrode is one or more of Au, Ag, Ru, W, Mo, Ir, Al, Pt, Nb and Hf, and a thickness of the material of the first electrode ranges from 100 nm to 300 nm; a material of the second electrode is one or more of Au, Ag, Ru, W, Mo, Ir, Al, Pt, Nb and Hf; a thickness of the material of the second electrode ranges from 100 nm to 300 nm.

12. A method for preparing a bulk acoustic wave resonator, wherein the method comprises:
S11: providing a temporary substrate;
S12: forming a piezoelectric film on the temporary substrate, the piezoelectric film sequentially comprising n layers of polarized piezoelectric films, any two adjacent layers of the polarized piezoelectric films having opposite polarities, wherein n≥2;
S13: forming a first electrode on the piezoelectric film;
S14: providing a substrate, bonding the substrate to the first electrode to secure the substrate while forming an acoustic mirror between the substrate and the first electrode, and removing the temporary substrate; and
S15: forming a second electrode on the piezoelectric film.

13. The method of preparing a bulk acoustic wave resonator according to claim 12, wherein polarized piezoelectric films of different polarities are grown in the same way, or in different ways.

14. The method of preparing a bulk acoustic wave resonator according to claim 12, wherein the method further comprises S16: preparing an electrode lead-out structure of the first electrode and the second electrode by:
S21: forming a via penetrating the piezoelectric film and exposing a surface of the first electrode, depositing in the via a first electrode lead-out structure connected to the first electrode;
S22: forming a second electrode lead-out structure connected to the second electrode.
